(19) United States
(12) Patent Application Publication
(10) Pub. No.: US 2006/0175718 A1
(43) Pub. Date: Aug. 10, 2006

(54) Semiconductor device and method of manufacturing the same

(75) Inventor: Hiroyuki Nitta, Yokkaichi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/332,175

(22) Filed: Jan. 17, 2006

(30) Foreign Application Priority Data
Jan. 17, 2005 (JP) 2005-9362

(51) Int. Cl. H01L 23/544

(52) U.S. Cl. 257/797

(57) ABSTRACT

A semiconductor device includes a semiconductor substrate having a first element isolation trench with a first opening width and a second element isolation trench with a second opening width larger than the first opening width, the first and second element isolation trenches having respective inner surfaces, the second element isolation trench having opposed sidewalls and bottom, a first element-isolating insulation film formed on the inner surfaces of the first and second element isolation trenches, a second element-isolating insulation film formed on the first element-isolating insulation film so as to fill the first element isolation trench and further formed on the first element-isolating insulation film formed on the sidewall of the second element isolation trench, and a third element-isolating insulation film provided on the second element-isolating insulation film and the first element-isolating insulation film formed on the bottom of the second element isolation trench, so as to fill the second element isolation trench.

### CROSS-REFERENCE TO RELATED APPLICATIONS

This application is based upon and claims the benefit of priority from the prior Japanese Patent Application No. 2005-9362, filed on Jan. 17, 2005, the entire contents of which are incorporated herein by reference.

### BACKGROUND OF THE INVENTION

1. Field of the Invention

The present invention relates to a semiconductor device having a shallow trench isolation (STI) formed by burying insulation films in element isolation trenches with different opening widths and a method of manufacturing such a semiconductor device.

2. Description of the Related Art

Shallow trench isolation (STI) has recently been employed as a method of isolating elements in semiconductor devices. The STI is superior in the flatness and refinement. However, the refinement has currently progressed to a minimum width of about 70 nm. This refinement level results in the following difficulty: a silicon oxide film is widely used as a buried member for an element isolation region in the STI method and formed by a high density plasma chemical vapor deposition (HDP-CVD) method. However, since an aspect ratio has become high in the burying, it is difficult to fill an element isolation region with the aforesaid silicon oxide film sufficiently. For example, JP-A-2003-31650 discloses a technique to overcome the above-described problem. The disclosed technique employs polysilazane as a coating type silicon oxide film to fill the a trench of the STI.

The technique disclosed in the aforesaid reference has the following technical problem in relation to a semiconductor device with element isolation trenches with different opening widths. Void sometimes results from the forming of an HDP film or the like. When the void is to be filled with the coating type silicon oxide film, heat treatment is necessitated in order that the silicon oxide film may be formed. The reason for execution of the heat treatment is as follows: when densification is not sufficient in a process of filling the STI with the coating type silicon oxide film (polysilazane film), the density of the film is reduced and an etching rate is increased such that it is difficult to control the etching rate during the process. Accordingly, heat treatment is carried out in an N₂ atmosphere at 80° C. for 30 minutes before subsequent processing, for example. In this case, however, since the polysilazane film has a large shrinkage relative to the HDP film, crack occurs in a boundary between polysilazane and HDP in an STI with a width not less than a predetermined value. Polycrystalline silicon serving as a control gate enters the region of crack, whereupon failure in the breakdown voltage occurs between a gate and the silicon substrate.

Furthermore, when the polysilazane film is used, high-density carbon contained in an organic solvent remains as an impurity in the film of the STI. The carbon is diffused in the aforesaid heat treating step, forming positive fixed charge in the silicon substrate located near the boundary of STI. The fixed charge reduces the threshold in an end of the element forming area of an N-channel type MOS transistor such that a leak current in the off-state is increased.

### SUMMARY OF THE INVENTION

Therefore, an object of the present invention is to provide a semiconductor device which can be formed without an adverse effect on the characteristics of an element even when element isolation regions formed by burying insulation films in the element isolation trenches have different opening widths, and a method of manufacturing the semiconductor device.

In one aspect, the invention provides a semiconductor device comprising a semiconductor substrate having a first element isolation trench with a first opening width and a second element isolation trench with a second opening width larger than the first opening width, the first and second element isolation trenches having respective inner surfaces, the second element isolation trench having opposed sidewalls and bottom, a first element-isolating insulation film formed on the inner surfaces of the first and second element isolation trenches, a second element-isolating insulation film provided on the first element-isolating insulation film so as to fill the first element isolation trench and formed on the first element-isolating insulation film formed on the sidewall of the second element isolation trench, and a third element-isolating insulation film provided on the second element-isolating insulation film and the first element-isolating insulation film formed on the bottom of the second element isolation trench, so as to fill the second element isolation trench.

In another aspect, the invention provides a method of manufacturing a semiconductor device, comprising forming at least an insulating film on a semiconductor substrate, etching the insulating film and the semiconductor substrate by a photolithography process, thereby forming a first element isolation trench with a first opening width and a second element isolation trench with a second opening width larger than the first opening width, the first and second element isolation trenches having respective inner surfaces, the second element isolation trench having an inner surface and bottom, forming a first element-isolating insulation film on the inner surfaces of the first and second element isolation trenches, forming a second element-isolating insulation film on the first element-isolating insulation film formed on the inner surfaces of the first and second element isolation trenches so that the first element isolating insulation film has such a film thickness as to be capable of filling the first element isolation trench, and forming a third element-isolating insulation film on the second element-isolating insulation film formed in the second element isolation trench so that the second element isolation trench is filled by the third element-isolating insulation film.

### BRIEF DESCRIPTION OF THE DRAWINGS

Other objects, features and advantages of the present invention will become clear upon reviewing the following description of the embodiment with reference to the accompanying drawings, in which:

FIGS. 1A and 1B are schematic sectional views of a memory area region and a peripheral circuit area of a semiconductor device in accordance with one embodiment of the present invention respectively;

FIGS. 2A and 2B are plan views corresponding to respective views of FIGS. 1A and 1b;

FIGS. 3A through 9B are schematic sectional views showing the manufacturing process;

FIGS. 10A and 10B are views similar to FIGS. 1A and 1B respectively, showing a second embodiment of the invention;

FIGS. 11A through 12B are schematic sectional views showing the manufacturing process in the second embodiment;

FIGS. 13A and 13B are views similar to FIGS. 1A and 1B respectively, showing a third embodiment of the invention;

FIGS. 14A through 17B are schematic sectional views showing the manufacturing process in the third embodiment;

FIGS. 18A and 18B are views similar to FIGS. 1A and 1B respectively, showing a fourth embodiment of the invention; and

FIGS. 19A through 22B are schematic sectional views showing the manufacturing process in the fourth embodiment.

### DETAILED DESCRIPTION OF THE INVENTION

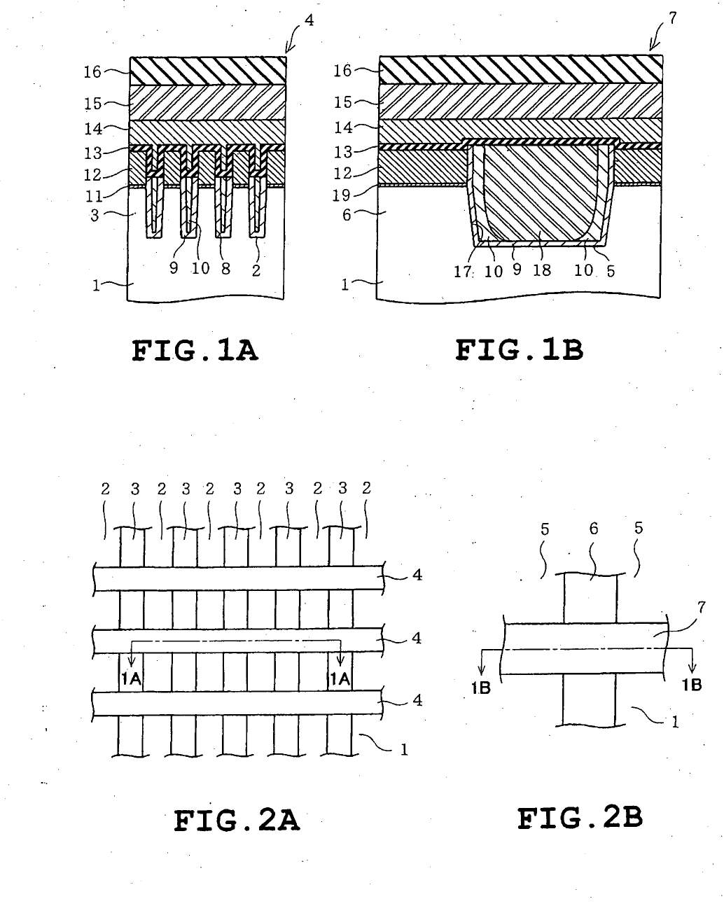

A first embodiment of the invention will be described with reference to FIGS. 1A to 9B. The invention is applied to a NAND flash memory in the embodiment. FIGS. 1A through 2B illustrate transistors formed in memory cell and peripheral circuit areas of the NAND flash memory are shown. Referring first to FIG. 2A showing the memory cell area, a silicon substrate 1 serving as a semiconductor substrate is formed with a shallow trench isolation (STI) 2 serving as an element isolation area. As a result, an active area 3 is separately formed as an element forming area. In this case, the STI 2 is formed by burying an insulating film in a first element isolation trench having a small opening width (first opening width). A number of gate electrodes 4 are formed at predetermined intervals in a direction perpendicular to the active area 3. Memory cell transistors are formed at intersections of the gate electrodes 4 and active areas 3. Each memory cell transistor is formed with a floating gate. Each gate electrode 4 is formed on the corresponding floating gate with the insulating film being interposed therebetween.

Referring now to FIG. 2B, the peripheral circuit area is shown. The STI 5 serving as an element isolation area is formed on the silicon substrate 1 in the same manner as described above. As a result, an active area 6 is separately formed as an element forming area. A gate electrode 7 is formed so as to extend in a direction perpendicular to the active area 6. The STI 5 is formed by burying an insulating film in a second element isolation trench having a large opening width (second opening width). Peripheral circuit transistors are formed at intersections of the gate electrode 7 and the active areas 6. Each memory cell transistor is formed with a floating gate. Such transistors are also on other parts of the peripheral circuit area. Various transistors are also formed to drive the memory cell transistors such high and low breakdown voltage transistors.

The sectional structure will now be described with reference to FIGS. 1A and 1B. FIG. 1A illustrates a section taken along line 1A-1A in FIG. 2A or a section of the gate electrode 4 of the memory cell area taken in the direction of formation thereof. FIG. 1B illustrates a section taken along line 1B-1B in FIG. 2B or a section of the gate electrode 7 of the peripheral circuit area taken in the direction of formation thereof.

Referring first to FIG. 1A, the silicon substrate 1 is formed with the STIs 2 with a pitch of 140 nm. Each STI 2 is formed by burying a high temperature oxide (HTO) film 9 and a polysilazane film 10 in an element isolation trench 8 formed so as to have a first opening width or small opening width (d1 in FIG. 4A). The HTO film 9 serves as a first element-isolating insulation film. The polysilazane film 10 is a coating type oxide film and serves as a second element-isolating insulation film. The HTO film 9 is formed on sidewalls and bottom both of which constitute an inner surface of the first element isolation trench 8. The HTO film 9 has a film thickness of 20 nm, for example. The polysilazane film 10 has such a film thickness as to be capable of filling a space defined by the HTO film 9 in the first element isolation trench 8.

Each STI 2 has an upper surface located higher than the surface of the silicon substrate 1. A gate insulating film such as silicon oxide film 11 is formed on a surface of the active area 3 of the silicon substrate 1 isolated by each STI 2. The silicon oxide film 11 has a film thickness of 8 nm, for example. A first polycrystalline silicon film 12 is stacked on an upper side of the silicon oxide film 11. The first polycrystalline silicon film 12 constitutes a floating gate and has a film thickness of 140 nm. The first polycrystalline silicon film 12 has the same width as the active area 3 and is formed so that an upper surface thereof is located higher than the upper surface of the STI 2. An oxide-nitride-oxide (ONO) film 13 is formed on the upper surfaces of the STI 2 and first polycrystalline silicon film 12 and has a film thickness of about 15 nm. The ONO film 13 serves as an interpolisilicon insulating film formed between a floating gate electrode and a control gate electrode.

Stacked on the upper surface of the ONO film 13 are a second polycrystalline silicon film 14, a tungsten-silicon (WSi) film 15 and a silicon oxide film 16 sequentially. These films 14, 15 and 16 constitute a control gate electrode. In this case, the second polycrystalline silicon film 14 has an upper surface flattened so that irregularity of the ONO film 13 is resolved.

Referring now to FIG. 1B showing a transistor of the peripheral circuit area, STIs 5 are formed at predetermined intervals in the silicon substrate 1, although only one STI 5 is shown. A second element isolation trench 17 has a second opening width or large opening width (d2 in FIG. 4B). An HTO film 9 serving as a first element-isolating insulation film is formed on an inner surface of the trench 17 or side walls and bottom of the trench 17. The HTO film 9 has a film thickness of 20 nm. The polysilazane film 10 serving as a second element-isolating insulation film is formed on the HTO film 9 formed on sidewalls of the second element isolation trench 17. The polysilazane film 10 has a film thickness of about 30 nm. An HDP film 18 serving as a third element-isolating insulation film is formed so as to fill the space defined by the polysilazane films 10 and the upper surface of the HTO film 9 in the second element isolation trench 17.

The STI 5 has an upper surface located higher than the surface of the silicon substrate 1. A silicon oxide film 19 serving as a gate insulating film for a high breakdown voltage transistor is formed on a surface of the active area 6 isolated by each STI 5. The silicon oxide film 19 has a film thickness of about 40 nm. Stacked on the upper surface of the silicon oxide film 11 are the first polycrystalline silicon film 12 constituting the gate electrode, ONO film 13, second polycrystalline silicon film 14, WSi film 15 and silicon oxide film 16 sequentially.

In the foregoing arrangement, the STI 12 is formed by filling the interior of the first element isolation trench 8 with the HTO film 9 and polysilazane film 10. The STI 5 is formed by filling the interior of the second element isolation trench 17 with the HTO film 9, polysilazane film 10 and HDP film 18. Thus, the first element isolation trench 8 with the small opening width is reliably filled with the polysilazane film 10, and a small amount of polysilazane used in the manufacturing step is used for the second element isolation trench 17 with the large opening depth. A large amount of polysilazane film used in the second trench 17 with the large opening width sometimes results in the peeling of film due to film shrinkage or off-leak deterioration of a transistor with formation of fixed charge due to carbon as impurity. However, the above-described arrangement can restrain the peeling of film or off-leak deterioration of a transistor.

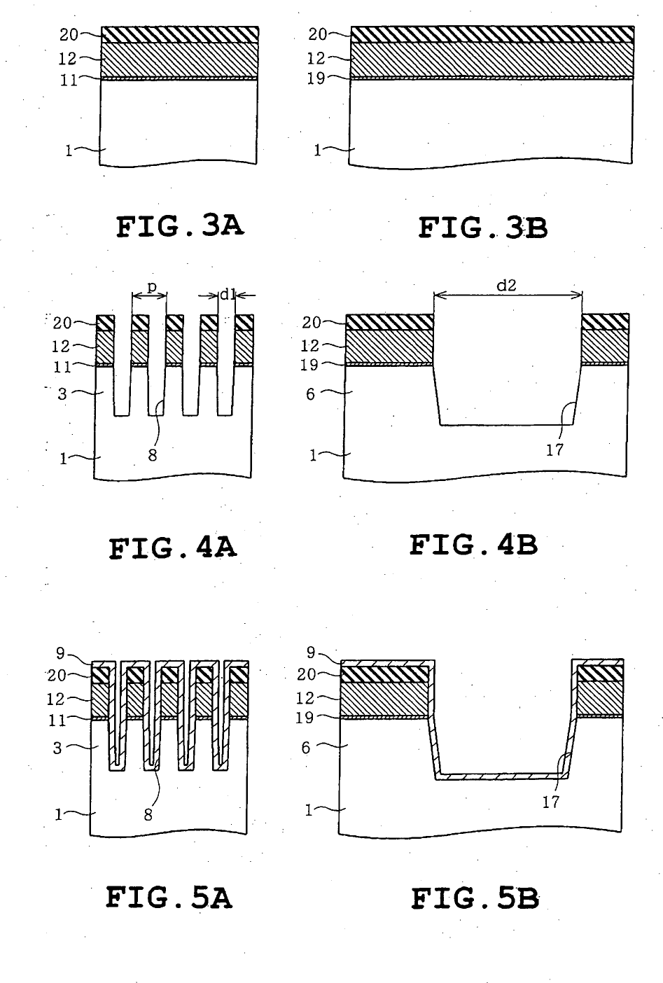

The manufacturing steps of the foregoing arrangement will be described with reference to FIGS. 3A through 9B. Referring first to FIGS. 3A and 3B, a silicon oxide film 11 is formed on the silicon substrate 1 by a thermal oxidation technique. The silicon oxide film 11 serves as a gate insulating film and has a film thickness of 8 nm. The silicon oxide film 11 functions as a gate oxide film of a memory transistor as described above. Furthermore, a silicon oxide film 19 serving as a gate oxide film is formed on a part of the peripheral circuit area in which a high breakdown voltage transistor is formed although a manufacturing step for the film 19 is not shown.

Subsequently, the polycrystalline silicon film 12 is formed by a low pressure chemical vapor deposition (CVD) process so as to have a film thickness of 140 nm. The polycrystalline silicon film 12 functions as a floating gate electrode. A silicon nitride film 20 is then formed on the polycrystalline silicon film 12 by the low pressure CVD. The silicon nitride film 20 serves as a mask material and a stopper in the formation of STI and has a film thickness of 70 nm.

Successively, photoresist is patterned into a predetermined configuration corresponding to the element isolation trench by the photolithography technique as shown in FIGS. 4A and 4B. The films 20, 13, 12, 11 and 19 and silicon substrate 1 are etched by a reactive ion etching (RIE) method while the patterned photoresist serves as a mask. The first element isolation trench 8 with a small opening width is formed in the memory cell area, whereas the second element isolation trench 17 with a large opening width is formed in the peripheral circuit area. Subsequently, the photoresist is removed by an ashing technique.

Subsequently, the first and second element isolation areas and the silicon substrate 1 are oxidized by a rapid thermal oxidation (RTO) method by the depth of 4 nm. Thereafter, the HTO film 9 having a high coverage is formed over the whole side of the silicon substrate 1 so as to have such a film thickness that does not cause void as the result of closure of the opening of the trench 8, for example, 20 nm.

Subsequently, the polysilazane film 10 serving as a coating type oxide film is applied over the whole substrate so that a necessary thickness is obtained for completely filling the first element isolation trench 8 of the memory cell area, for example, 30 nm, and an oxidation process is carried out for the purpose of removal of impurities and film refinement in an atmosphere of moisture at a low temperature, for example, 400° C. Furthermore, a heat treatment is carried out in an inert atmosphere at a temperature ranging from 800° C. to 900° C. In this case, film quality is improved in the conversion of the polysilazane film 10 to a silicon oxide film when the oxidation process is carried out under strong conditions. However, bird beak is simultaneously formed on the silicon oxide film 11 serving as a gate insulating film, deteriorating the characteristic of the film. Accordingly, it is difficult to set an amount of oxidation to a sufficiently large value. Furthermore, the polysilazane film 10 can be prevented from being buried in the second element isolation trench since the polysilazane film 10 formed in the second element isolation trench is thinner (30 nm, for example) as compared with the opening width of the second element isolation trench. Since the polysilazane coating film has fluidity, a part 10a of the polysilazane film located at a corner where the sidewall and bottom in the second trench 17 cross each other is slightly thicker and rounded as compared with the other part of the polysilazane film.

The polysilazane film 10 is then etched back by the RIE method as shown in FIGS. 7A and 7B. In this case, a part of the polysilazane film 10 formed on the bottom of the second element isolation trench 17 is removed so that the HTO film 9 formed on the bottom of the trench 17 is exposed. As a result, the polysilazane film 10 remains only on the HTO film 9 formed on the sidewalls of the second element isolation trench 17. In the memory cell area, the polysilazane film 10 remains only in the first element isolation trench 8.

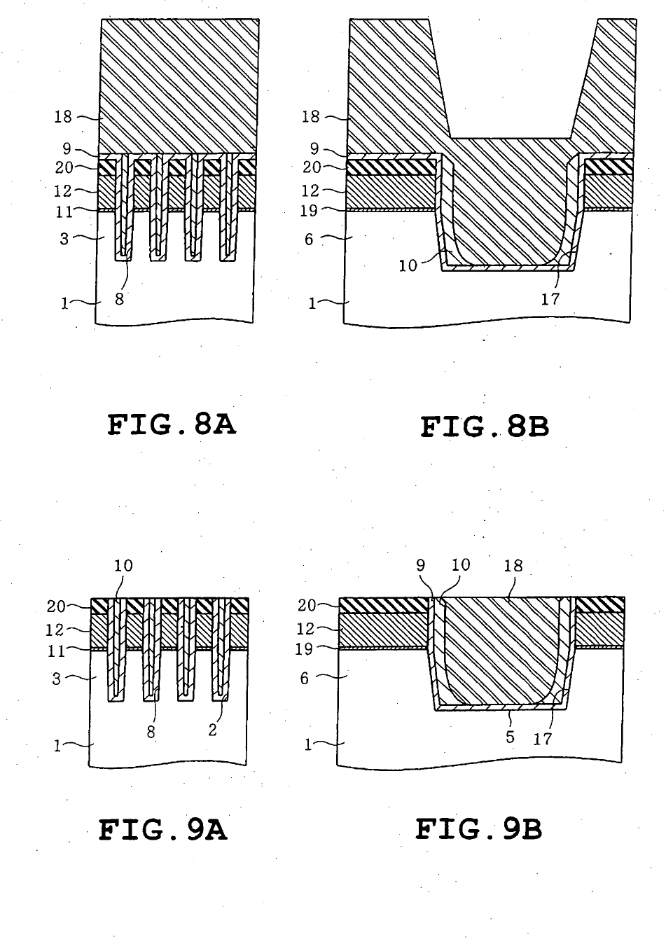

Subsequently, a high-density-plasma (HDP) film (silicon oxide film) 18 is formed by an HDP-CVD method as shown in FIGS. 8A and 8B. In this case, the HDP film 18 is formed so as to have such large film thickness than the interior of the second element isolation trench 17 is completely filled. In the memory cell area, the HDP film 18 is formed on the HTO film 9 and the polysilazane film 10 both of which are in the state as shown in FIG. 7A.

Subsequently, the HDP film 18 and the HTO film 9 are polished by the CMP method with the silicon nitride film 20 serving as a stopper film, whereby a flattening process is carried out, as shown in FIGS. 9A and 9B. The STI 2 with the HTO film 9 and the polysilazane film 10 buried therein is formed in the first element isolation trench 8, whereas the STI 5 with the HTO film 9, polysilazane film 10 and HDP film 18 buried therein is formed in the second element isolation trench 17. Although the STI 5 is formed with the polysilazane film 10, the film thickness of the film 10 is no more than 30 nm and accordingly, an occupancy rate of the film 10 in the STI 5 is small.

Subsequently, the HTO film 9 and the polysilazane film 10 in the first element isolation trench 8 of the memory cell area are etched back so that levels of the films 9 and 10 are located in the middle of the first polycrystalline silicon film 12, as shown in FIGS. 1A and 1B. Thereafter, the silicon nitride film 20 is removed. Furthermore, the ONO film 13 is deposited 15 nm and subsequently, the second polycrystalline silicon film 14 and WSi film 15 both constituting the control gate are formed, and the silicon nitride film 16 is formed. The silicon nitride film 16 serves as a mask used in the formation of the gate electrode.

Subsequently, an etching process is carried out with the use of the silicon nitride film as the mask by the photolithography technique, the RIE technique and the like. As a result, a pattern structure of the gate electrodes 4 and 7 is obtained as shown in FIGS. 2A and 2B.

As the result of employment of the above-described manufacturing steps, the HTO film 9 and the polysilazane film 10 can completely be buried in the first element isolation trench 8 of the memory cell area with a high aspect ratio. Moreover, a thin polysilazane film 10 is formed in the second element isolation trench 17 with the large opening width. This can improve the burying characteristic and prevent the peeling of film due to film shrinkage or off-leak deterioration of a transistor with formation of fixed charge due to carbon as impurity.

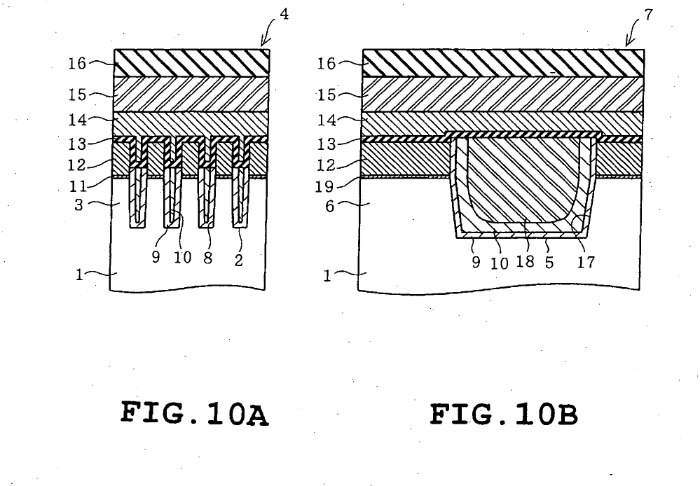

FIGS. 10A through 12B show a second embodiment of the invention. The second embodiment differs from the first embodiment in the shape of the polysilazane film 10 formed on the inner surface of the second element isolation trench 17. More specifically, the polysilazane film 10 is further formed on the bottom of the second trench 17 which also constitutes the inner surface thereof, as shown in FIG. 10B. The second trench 17 with a large opening width has a larger capacity for the filling of the polysilazane film 10 in the second embodiment than in the first embodiment. However, the polysilazane film 10 has a small thickness which is no more than 30 nm and accordingly a small occupancy in the trench 17. Consequently, the second embodiment can achieve substantially the same effect as the first embodiment. Furthermore, the foregoing arrangement can reduce the number of steps of the manufacturing process as will be described later.

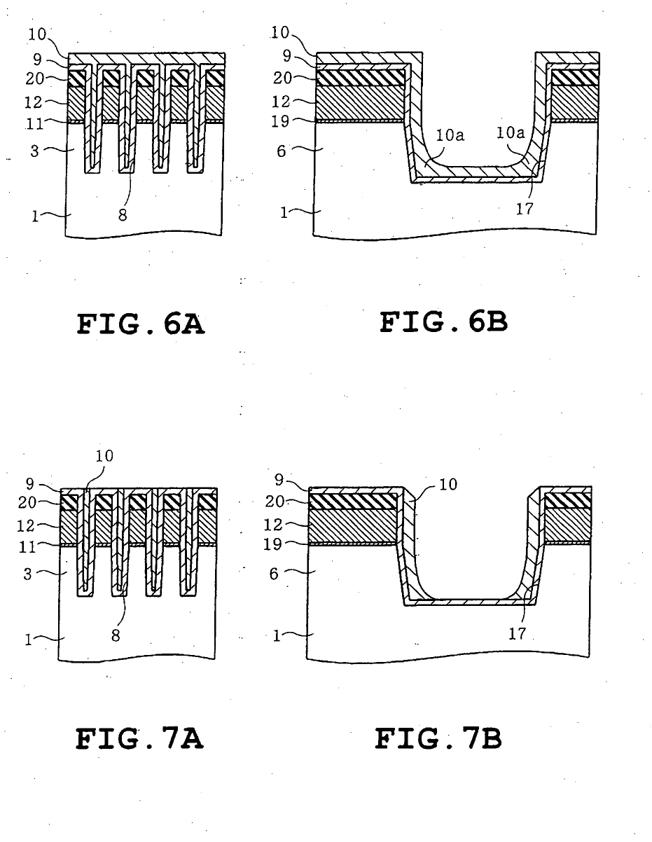

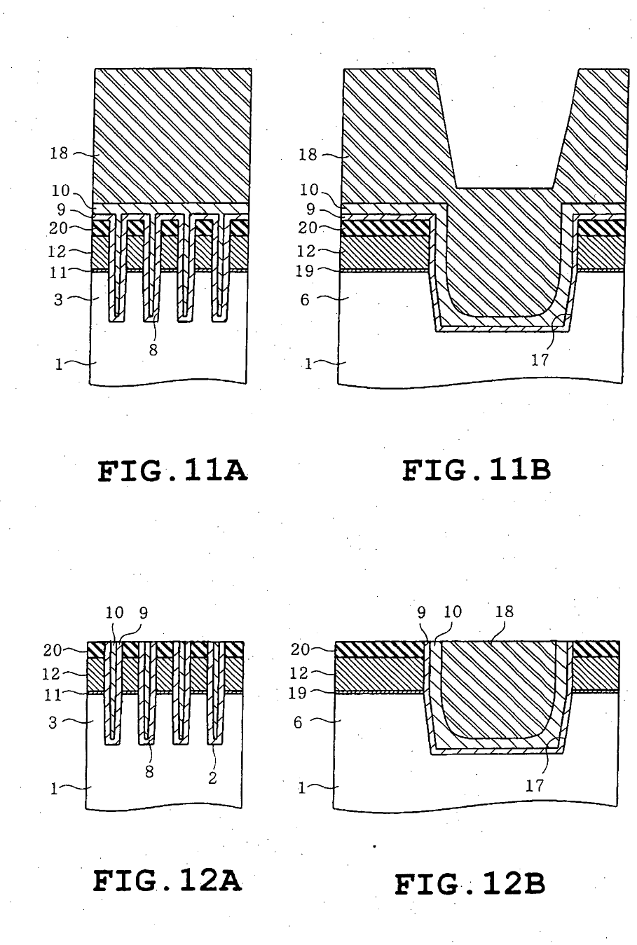

In the first embodiment, the step as shown in FIGS. 6A and 6B is carried out and thereafter, an etchback process is carried out for the polysilazane film 10 so that the memory cell and peripheral circuit areas are removed from the flat part. In the second embodiment, however, the aforesaid etchback process is eliminated. Accordingly, when the HDP film 18 has been formed, the polysilazane film 10 remains as shown in FIGS. 11A and 11B.

Subsequently, the HDP film 18, polysilazane film 10 and the HTO film 17 are polished with the silicon nitride film 20 serving as a stopper. As a result, as shown in FIGS. 12A and 12B, the second embodiment can achieve the same arrangement of the memory cell area as the first embodiment. Furthermore, the polysilazane film 10 remains on the HTO film 9 on the inner surface of the second trench 17 or on the sidewalls and bottom of the second trench.

The following effects can be achieved from the above-described manufacturing process: an amount of polysilazane film 10 can be reduced and moreover, when an adverse effect of the peeling of film or formation of fixed charge is small, the etchback process can be eliminated in the manufacturing process which can obtain the arrangement providing substantially the same characteristic as in the first embodiment. Consequently, the number of steps can be reduced and accordingly, the manufacturing time can be reduced.

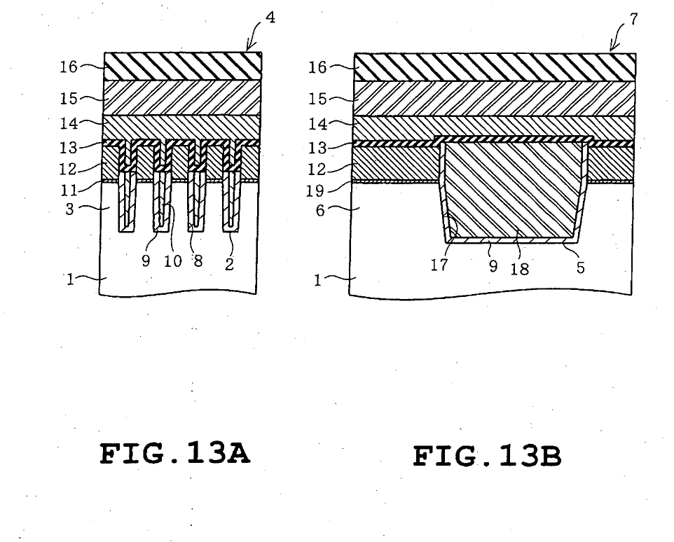

FIGS. 13A through 17B illustrate a third embodiment of the invention. The differences of the third embodiment from the first embodiment will be described. The arrangement shown in FIG. 13A is the same as that in FIG. 1A. The arrangement shown in FIG. 13B resides in obviating the polysilazane film 10. As a result, the HTO film 9 is formed on the inner surface of the second element isolation trench 17 and the HDP film 18 is buried in a space defined by the HTO film 9 in the trench. Accordingly, the third embodiment can overcome a technical problem resulting from the use of the polysilazane film 10 in the second trench 17. Consequently, an adverse effect of the peeling of film or formation of fixed charge both resulting from the polysilazane film 17 can be prevented more completely.

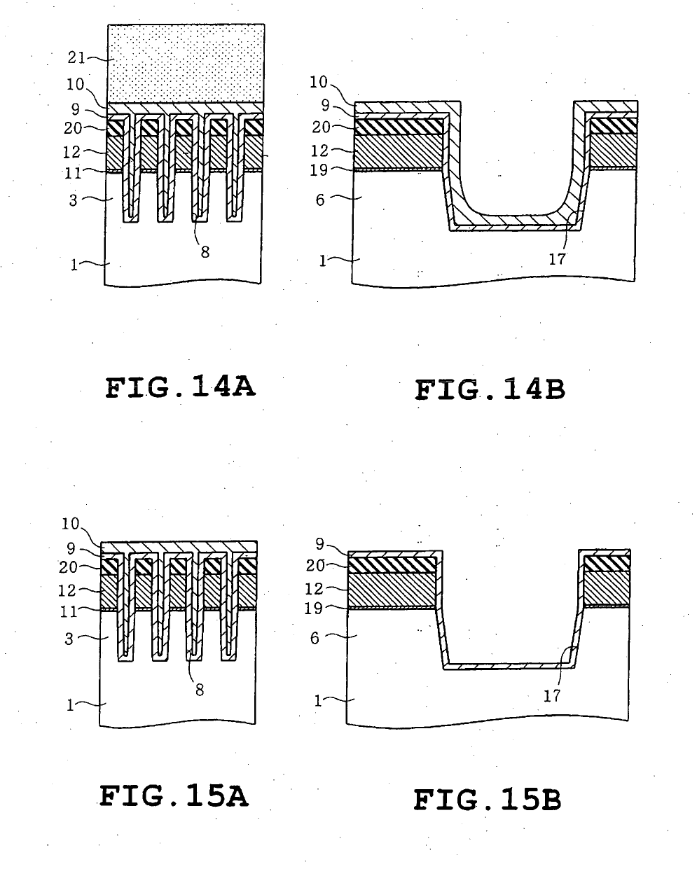

The manufacturing process for the foregoing arrangement will be described with particular attention to the difference of the third embodiment from the first embodiment. FIGS. 14A and 14B show the memory cell area patterned so that the area is covered with the photoresist 21 by the photolithography process in addition to the arrangement as shown in FIGS. 6A and 6B in the first embodiment. Next, as shown in FIGS. 15A and 15B, the polysilazane film 10 in the peripheral circuit area is removed using, for example, a solution of ammonium fluoride (NH₄F) with the photoresist 21 serving as a mask. Subsequently, the photoresist 21 is removed. In this case, a heat treatment is carried out in the oxidative atmosphere with moisture added at a low temperature of about 400° C. for the for the purpose of film refinement and removal of impurities. Since the temperature in the heat treatment is low, a wet etching rate of the polysilazane film 10 is rapidly increased relative to a thermal oxidation film. This property is used for selective removal of the polysilazane film 10 from the HTO film 9.

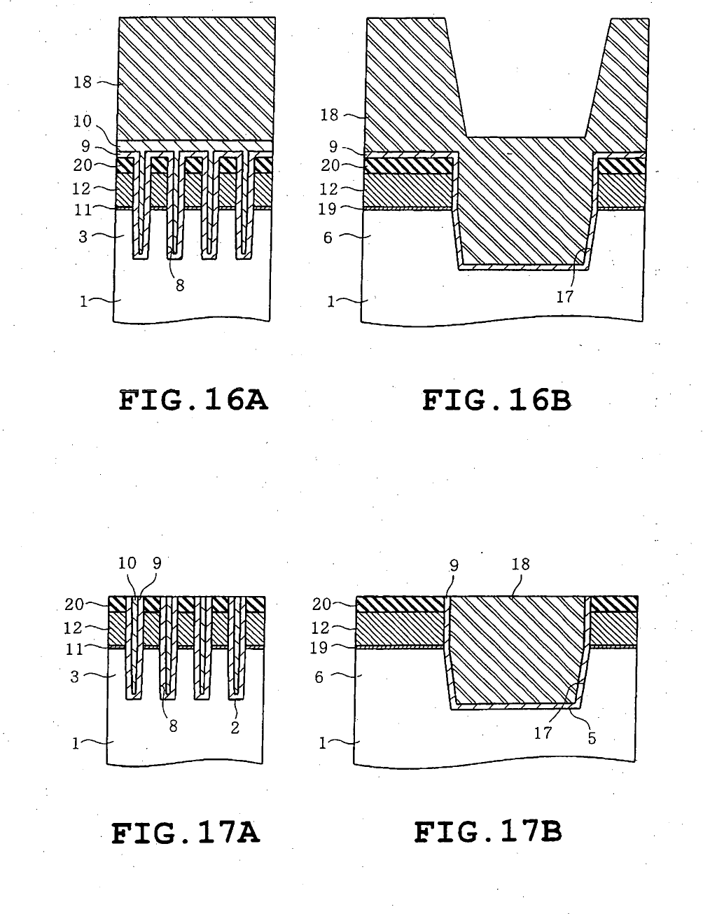

Subsequently, the HDP film 18 is formed in the second element isolation trench 17 of the large opening width of the peripheral circuit area so as to have such a film thickness that the HDP film 18 can completely fill the trench 17, as shown in FIGS. 16A and 16B. Successively, as shown in FIGS. 17A and 17B, the HDP film 18, polysilazane film 10 and HTO film 9 are cut by the CMP method with the use of the silicon nitride film 20 as a stopper film, thereby being flattened.

Subsequently, the HTO film 9 and polysilazane film 10 both in the first element isolation trench 8 of the memory cell area are etched back and the silicon nitride film 20 is removed in the same manner as described above. Successively, the ONO film 13, second polycrystalline silicon film 14, WSi film 15 and silicon nitride film 16 are formed, whereupon the arrangement as shown in FIGS. 13A and 13B is obtained. Furthermore, a pattern structure of the gate electrodes 4 and 7 is formed by the photolithography technique, RIE technique or the like.

According to the third embodiment, no polysilazane film 10 is used in the second element isolation trench 17 of the peripheral circuit area although the number of steps in the manufacturing process is slightly increased as compared with the first embodiment. Consequently, the peeling of film or formation of fixed charge caused by the polysilazane film 10 can reliably be prevented.

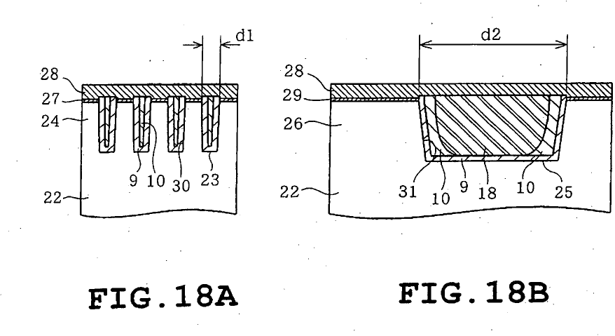

FIGS. 18A through 22B illustrate a fourth embodiment of the invention. The difference of the fourth embodiment from the first embodiment will be described. Differing from the previous embodiments, the fourth embodiment is directed to a semiconductor device, for example, a memory device such as dynamic random access memory (DRAM), employing a manufacturing process for forming a gate electrode after an element isolation area has been formed.

More specifically, an STI 23 with a small width is formed in a memory cell area of the silicon substrate 22 serving as a semiconductor substrate as shown in FIG. 18A. An active area 24 serving as an element forming area is formed on the silicon substrate 22 so as to be separated by the STI 23. Furthermore, an STI 25 with a large width is formed in the peripheral circuit area of the silicon substrate 22 as shown in FIG. 18B. An active area 26 serving as an element forming area is formed so as to be separated by the STI 25.

A silicon oxide film 27 is formed on a surface of the active area 24 of the memory cell area. The silicon oxide film 27 serves as a gate insulating film for a memory cell transistor and has a film thickness of 8 nm. A polycrystalline silicon film 28 is formed so as to cover the silicon oxide film 27 and STI 23. The polycrystalline silicon film 28 serves as a gate electrode material. A silicon oxide film 29 is formed on the surface of the active area 26 of the peripheral circuit area. The silicon oxide film 29 serves as a gate insulating film of a high breakdown voltage transistor for driving a memory cell transistor and has a film thickness of 40 nm. The polycrystalline silicon film 28 is formed so as to cover the silicon oxide film 29 and STI 25.

Regarding the aforesaid STI 23, a first element isolation trench 30 formed so as to have a small opening width (as shown by d1 in FIG. 18A) is filled by the HTO film 9 serving as a first element-isolating insulation film and the polysilazane film 10 which is a coating type oxide film serving as a second element-isolating insulation film. In this case, the HTO film 9 is formed on the sidewalls and bottom both of which constitute an inner surface of the first element isolation trench 30. The HTO film 9 has a film thickness of 20 nm, for example. The polysilazane film 10 has such a film thickness as to be capable of filling the remaining space in the interior of the HTO film 9.

The STI 25 is formed in a second element isolation trench 31 formed so as to have a large opening width (as shown by d2 in FIG. 18B). The HTO film 9 serving as the first element-isolating insulation film is formed on the sidewalls and bottom both of which constitute an inner surface of the second element isolation trench 31. The HTO film 9 has a film thickness of 20 nm. The polysilazane film 10 serving as the second element-isolating insulation film is formed on the HTO film 9 formed on the sidewalls of the second element isolation trench 31. The polysilazane film 10 has a film thickness of about 30 nm. The HDP film 18 serving as a third element-isolating insulation film is formed so as to be buried in the remaining interior of the second element isolation trench 31.

According to the above-described arrangement, while the polysilazane film 10 is reliably buried in the first element isolation trench 30 with the small opening width, a small amount of polysilazane film 10 used in the manufacturing process is also used for the second element isolation trench 31 with the large opening width, as in the first embodiment. The above-described arrangement can prevent the film peeling due to film shrinkage in the case where a large amount of polysilazane film is used in the second element isolation trench 30 with a large opening width. The above-described arrangement can also prevent off leak deterioration of the transistor with formation of fixed charge resulting from carbon which is an impurity.

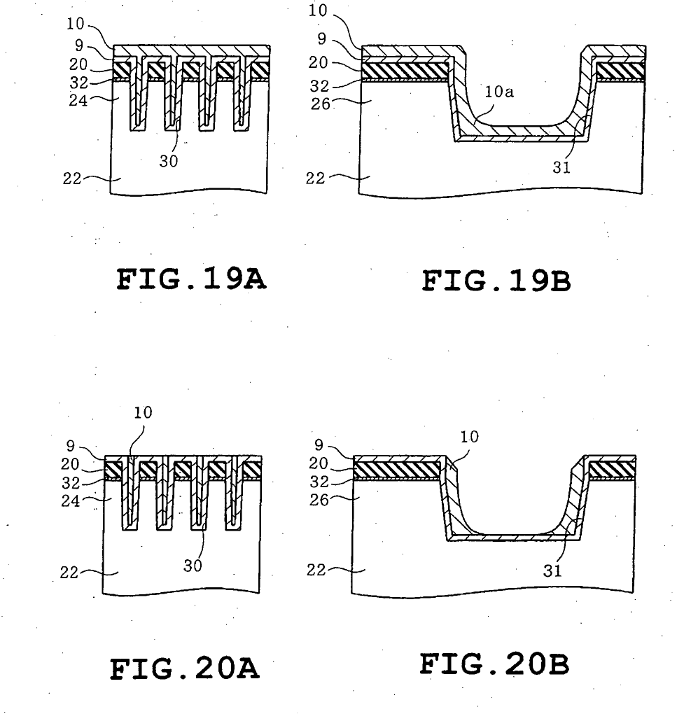

The manufacturing process of the foregoing arrangement will now be described briefly with reference to FIGS. 19A through 22B. Firstly, a silicon oxide film 32 is deposited by 6 nm on the semiconductor substrate, and the silicon nitride film 20 is deposited by 70 nm on the semiconductor substrate in turn. Photoresist is then patterned into a configuration corresponding to the shape of a element isolation trench by the photolithography method. The silicon nitride film 20, silicon oxide film 32 and silicon substrate 22 are etched by the RIE method with the patterned photoresist serving a mask. The first element isolation trench 30 with the small opening width is formed in the memory cell area, whereas the second element isolation trench 31 with the large opening width is formed in the peripheral circuit area. In this case, the element isolation trenches 30 are formed with a pitch of 140 nm, for example.

Next, the surface of the silicon substrate 22 corresponding to the first and second element isolation areas is oxidated 4 nm as shown in FIGS. 19A and 19B. Subsequently, the HTO film 9 is formed so as to have such a large film thickness that void is not formed in the element isolation area, for example, 20 nm. The polysilazane film 10 is coated so as to have such a film thickness as to fill the memory cell area completely, for example, 30 nm. A heat treatment is carried out in an atmosphere of moisture at a low temperature, for example, 400° C. so that the film is refined. In this case, the second element isolation trench 31 is adapted not to be filled with the polysilazane film 10 completely. Furthermore, the polysilazane film 10a includes a part where the bottom and the sidewalls cross each other.

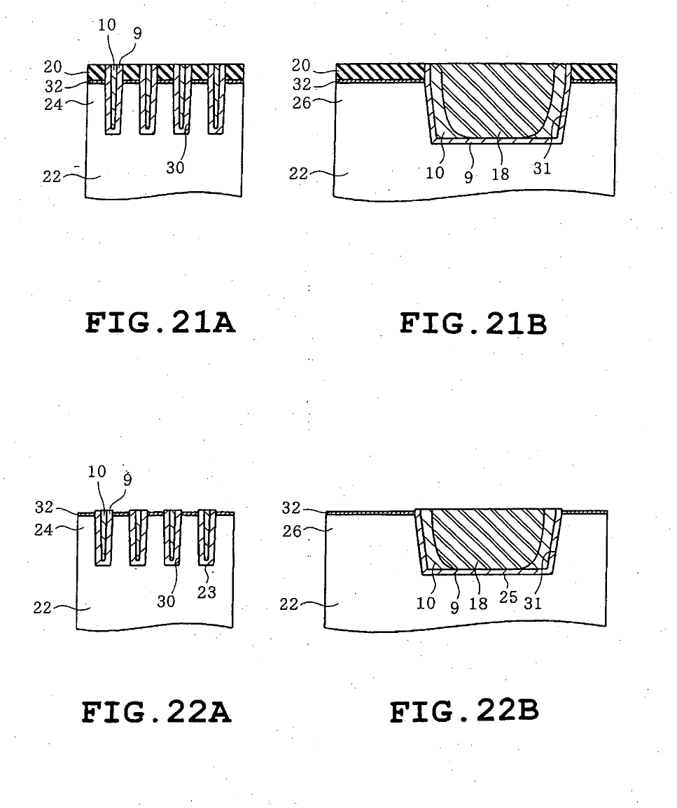

The polysilazane film 10 is etched back by the RIE method so that the film 10 remains only on the sidewalls in the second element isolation trench 31 as shown in FIGS. 20A and 20B. Successively, the HDP film 18 is formed so as to fill the second element isolation trench 31 completely as shown in FIGS. 21A and 21B. Thereafter, the HDP film 18 and HTO film 9 are cut by the CMP method with the silicon nitride film 20 used as a stopper film, thereby being flattened.

Subsequently, the polysilazane film 10 filling the first element isolation trench 30 in the memory cell area is refined so that an etching rate is restrained. For this purpose, a heat treatment process is carried out at 800° C. in an atmosphere of N₂ for 30 minutes. Thereafter, the polysilazane film 10, HTO film 9 and HDP film 18 are etched back using a solution of ammonium fluoride (NH₄F). As a result, the STIs 23 and 25 are formed.

Subsequently, the silicon nitride film 20 is selectively removed from the silicon oxide film 32 by a hot H₃PO₄ treatment.

Subsequently, the silicon oxide film 32 is delaminated using, for example, a solution of ammonium fluoride, and the gate 15 oxide films 27 and 29 are formed. Furthermore, the polycrystalline silicon film 28 serving as a gate electrode is formed on the gate oxide films 27 and 29. The manufacture sequence advances to a step of forming gate electrodes.

As the result of use of the above-described method, the first element isolation trench 30 of the minute pattern can completely be filled by the polysilazane film 10 which is a coating film in the method of manufacturing the semiconductor device in which STI such as a DRAM. At the same time, the film peeling due to film shrinkage and formation of fixed charge caused by carbon are critical when the polysilazane film 10 is used in the second element isolation trench 31. However, the film peeling and formation of fixed charge caused by carbon can be improved to a large degree by rendering an amount of polysilazane film minimum.

The polysilazane film 10 remains on the sidewalls of the second element isolation trench 31 in the fourth embodiment. However, as in the second embodiment, the polysilazane film 10 may remain on the bottom of the second element isolation trench 31 by simplifying the manufacturing process, instead. Furthermore, as in the third embodiment, only the element isolation area of the peripheral circuit area may be opened by the photolithography method and thereafter, the polysilazane film 10 of the peripheral circuit area may completely be removed by wet etching, instead.

The invention should not be limited to the above-described embodiments but may be modified or expanded. The opening widths of the first and second element isolation trenches should not be limited to the above-described. The opening widths of the element isolation trenches may take any suitable values. The coating type oxide film should not be limited to polysilazane but may be another spin-on-glass (SOG).

The foregoing description and drawings are merely illustrative of the principles of the present invention and are not to be construed in a limiting sense. Various changes and modifications will become apparent to those of ordinary skill in the art. All such changes and modifications are seen to fall within the scope of the invention as defined by the appended claims.

What is claimed is:

1. A semiconductor device comprising:
a semiconductor substrate having a first element isolation trench with a first opening width and a second element isolation trench with a second opening width larger than the first opening width, the first and second element isolation trenches having respective inner surfaces, the second element isolation trench having opposed sidewalls and bottom;
a first element-isolating insulation film formed on the inner surfaces of the first and second element isolation trenches;
a second element-isolating insulation film provided on the first element-isolating insulation film so as to fill the first element isolation trench and formed on the first element-isolating insulation film formed on the sidewall of the second element isolation trench; and
a third element-isolating insulation film provided on the second element-isolating insulation film and the first element-isolating insulation film formed on the bottom of the second element isolation trench, so as to fill the second element isolation trench.

2. A semiconductor device comprising:
a semiconductor substrate having a first element isolation trench with a first opening width and a second element isolation trench with a second opening width larger than the first opening width, the first and second element isolation trenches having respective inner surfaces, the second element isolation trench having an inner surface and bottom;
a first element-isolating insulation film formed on the inner surfaces of the first and second element isolation trenches;
a second element-isolating insulation film provided on the first element-isolating insulation film so as to fill the first element isolation trench and formed on the first element-isolating insulation film formed on the inner surface of the second element isolation trench; and
a third element-isolating insulation film provided on the second element-isolating insulation film so as to fill the second element isolation trench.

3. The semiconductor device according to claim 1, wherein the second element-isolating insulation film is a coating type oxide film.

4. The semiconductor device according to claim 2, wherein the second element-isolating insulation film is a coating type oxide film.

5. The semiconductor device according to claim 3, wherein the coating type oxide film is a polysilazane film.

6. The semiconductor device according to claim 4, wherein the coating type oxide film is a polysilazane film.

7. The semiconductor device according to claim 1, wherein the first element-isolating insulation film is a tetraethyl orthosilicate (TEOS). film or a high temperature oxide (HTO) film.

8. The semiconductor device according to claim 2, wherein the first element-isolating insulation film is a tetraethyl orthosilicate (TEOS) film or a high temperature oxide (HTO) film.

9. A method of manufacturing a semiconductor device, comprising:
forming at least an insulating film on a semiconductor substrate;
etching the insulating film and the semiconductor substrate by a photolithography process, thereby forming a first element isolation trench with a first opening width and a second element isolation trench with a second opening width larger than the first opening width, the first and second element isolation trenches having respective inner surfaces, the second element isolation trench having an inner surface and bottom;
forming a first element-isolating insulation film on the inner surfaces of the first and second element isolation trenches;
forming a second element-isolating insulation film on the first element-isolating insulation film formed on the inner surfaces of the first and second element isolation trenches so that the first element isolating insulation film has such a film thickness as to be capable of filling the first element isolation trench; and
forming a third element-isolating insulation film on the second element-isolating insulation film formed in the second element isolation trench so that the second element isolation trench is filled by the third element-isolating insulation film.

10. A method of manufacturing a semiconductor device, comprising:
forming at least an insulating film on a semiconductor substrate;
etching the insulating film and the semiconductor substrate by a photolithography process, thereby forming a first element isolation trench with a first opening width and a second element isolation trench with a second opening width larger than the first opening width, the first and second element isolation trenches having respective inner surfaces, the second element isolation trench having an inner surface and bottom;
forming a first element-isolating insulation film on the inner surfaces of the first and second element isolation trenches;
forming a second element-isolating insulation film on the first element-isolating insulation film formed in first and second element isolation trenches so that the second element-isolating insulation film has such a film thickness as to be capable of filling the first element isolation trench;
removing the second element-isolating insulation film formed in the second element isolation trench; and
filling the second element isolation trench with a third element-isolating insulation film so that the third element-isolating insulation film is located over the first element-isolating insulation film formed in the second element isolation trench which is exposed as a result of removal of the second element isolation trench.

11. The method according to claim 9, wherein a coating type oxide film is applied in the step of forming the second element-isolating insulation film.

12. The method according to claim 10, wherein a coating type oxide film is applied in the step of forming the second element-isolating insulation film.

13. The method according to claim 9, wherein the coating type oxide film is a polysilazane film.

14. The method according to claim 10, wherein the coating type oxide film is a polysilazane film.

15. The method according to claim 9, wherein a tetraethyl orthosilicate (TEOS) film or a high temperature oxide (HTO) film is formed by a chemical vapor deposition (CVD) in the step of forming the first element-isolating insulation film.

16. The method according to claim 10, wherein a tetraethyl orthosilicate (TEOS) film or a high temperature oxide (HTO) film is formed by a chemical vapor deposition (CVD) in the step of forming the first element-isolating insulation film.
